(19) United States
(12) Patent Application Publication
(10) Pub. No.: US 2021/0285109 A1
(43) Pub. Date: Sep. 16, 2021

(54) COATED BODY AND METHOD FOR COATING

(71) Applicant: Kennametal Inc., Latrobe, PA (US)

(72) Inventors: Joern Kohlscheen, Forchheim (DE); Debangshu Banerjee, Latrobe, PA (US)

(21) Appl. No.: 16/817,578

(22) Filed: Mar. 12, 2020

(51) Int. Cl. C23C 28/00; C23C 14/08; C23C 14/06

(52) U.S. Cl. CPC C23C 28/345; C23C 14/081; C23C 28/347; C23C 14/0676; C23C 14/0641

(57) ABSTRACT

A coated body has a substrate and a coating applied to the substrate by physical vapor deposition. The coating includes a main layer adjacent to the substrate and a multilayer adjacent to the main layer. The main layer includes a nitride of at least Al and Ti. The multilayer includes alternating layers of an oxide or oxynitride layer and a nitride layer. The oxide or oxynitride layer includes an oxide or oxynitride of at least one of Zr, Hf, and Cr. The nitride layer includes a nitride of at least one of Zr, Hf, and Cr. A metallic interlayer is between the main layer and the multilayer or between the oxide or oxynitride layer and the nitride layer of the multilayer.

### FIELD

The present application relates to a coated body, in particular a cutting tool, including a substrate and a coating on the substrate, and a method for coating a substrate.

### BACKGROUND

Cutting tools used for machining metals and metal alloys, such as steel and cast iron, typically consist of a main body and a coating applied to the main body. The coating is used to make the cutting insert harder and/or more wear-resistant and to improve the cutting properties. The coating may include one or more layers made of hard materials such as titanium nitride, titanium carbide, titanium carbon nitride, titanium aluminum nitride, and/or aluminum oxide. Physical vapor deposition (PVD) methods are typically used when depositing titanium nitride and titanium aluminum nitride. While effective in inhibiting wear and extending tool lifetime in a variety of applications, coatings based on single or multi-layer constructions of the foregoing materials have increasingly reached their performance limits, thereby calling for the development of new coating architectures for cutting tools.

The object of the present invention is to provide further coatings for cutting tools with improved performance and increased service life for cutting various metals and metal alloys.

### SUMMARY

In one embodiment, a coated body has a substrate and a coating applied to the substrate by physical vapor deposition. The coating includes a main layer adjacent to the substrate and a multilayer adjacent to the main layer. The main layer includes a nitride of at least Al and Ti. The multilayer includes alternating layers of an oxide or oxynitride layer and a nitride layer. The oxide or oxynitride layer includes an oxide or oxynitride of at least one of Zr, Hf, and Cr. The nitride layer includes a nitride of at least one of Zr, Hf, and Cr. A metallic interlayer is between the main layer and the multilayer or between the oxide or oxynitride layer and the nitride layer of the multilayer.

In another embodiment, a method for coating a substrate includes depositing a main layer on the substrate by physical vapor deposition under a nitrogen gas flow and depositing a multilayer on the main layer by physical vapor deposition by alternating between nitrogen gas flow and an oxygen or oxygen and nitrogen gas flow. The main layer includes a nitride of at least Al and Ti. The multilayer includes alternating layers of an oxide or oxynitride layer and a nitride layer. The oxide or oxynitride layer includes an oxide or oxynitride of at least one of Zr, Hf, and Cr. The nitride layer includes a nitride of at least one of Zr, Hf, and Cr. During at least one of the steps of depositing the main layer and depositing the multilayer, the at least one of the gas flows is reduced for a dwell period while continuing the physical vapor deposition to form a metallic interlayer between the main layer and the multilayer or between the oxide or oxynitride layer and the nitride layer of the multilayer.

Other embodiments of the disclosed coated body and method for coating will become apparent from the following detailed description, the accompanying drawings and the appended claims.

### BRIEF DESCRIPTION OF THE DRAWINGS

FIG. 1 is a perspective view of an exemplary coated body according to an embodiment described herein.

FIG. 2 is a representative view of a cross-section of a coating of a coated body according to an embodiment described herein.

FIG. 3 is a micrograph of a coated body produced according to a comparative example of the present description.

FIG. 4 is a micrograph of a coated body produced according to an inventive example of the present description.

### DETAILED DESCRIPTION

Embodiments described herein can be understood more readily by reference to the following detailed description and examples and their previous and following descriptions. However, the present description is not limited to the specific embodiments presented in the detailed description and examples. It should be recognized that these embodiments are merely illustrative of the principles of the present description.

According to the present description, a coated body includes a substrate and a coating applied to the substrate.

The coated body may have any shape not inconsistent with the objectives of the present description. In an aspect, the coated body may have the shape of a cutting tool. Cutting tools include, but are not limited to, indexable cutting inserts, end mills, saw blades, or drill bits. Indexable cutting inserts can have any desired ANSI standard geometry for milling or turning applications. The substrate of a coated cutting tool typically includes one or more cutting edges formed at the juncture of a rake face and at least one flank face of the substrate.

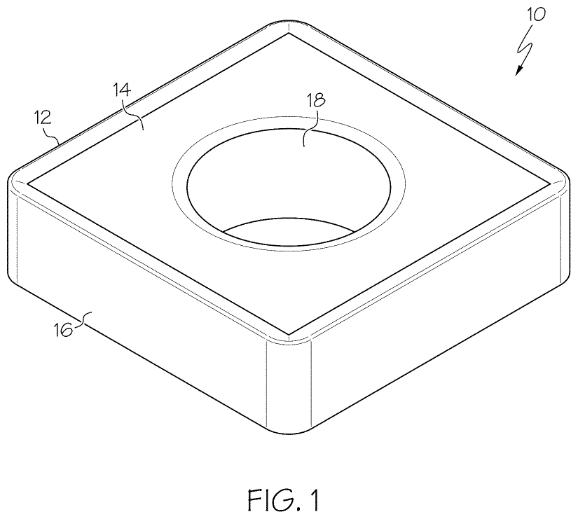

FIG. 1 illustrates a exemplary coated body 10 according to an example described herein. As illustrated in FIG. 1, the coated body 10 is in the form of a cutting insert. The cutting insert has cutting edges 12 formed at junctions of the substrate rake face 14 and flank faces 16. The cutting insert may also include an aperture 18 for securing the cutting insert to a tool holder. The cutting insert may have a variety of geometries and configurations, e.g. with or without chipbreakers, mounting hole or positive or negative rake angle.

The substrate of the coated body (e.g. cutting insert) may include any substrate not inconsistent with the objectives of the present description. Exemplary substrates for the coated body include substrates formed of cemented carbide, carbide, polycrystalline diamond, polycrystalline cubic boron nitride, ceramic, cermet, steel or other alloy.

In a specific example, the substrate is formed of cemented carbide. A cemented carbide substrate may include tungsten carbide (WC). WC can be present in any amount not inconsistent with the objectives of the present description. For example, WC can be present in an amount of at least 70 weight percent, in an amount of at least 80 weight percent, or in an amount of at least 85 weight percent. Additionally, a metallic binder of cemented carbide can include cobalt or cobalt alloy. Cobalt, for example, can be present in a cemented carbide substrate in an amount ranging from 1 weight percent to 15 weight percent. In some embodiments, cobalt is present in a cemented carbide substrate in an amount ranging from 5-12 weight percent or from 6-10 weight percent. Further, a cemented carbide substrate may exhibit a zone of binder enrichment beginning at and extending inwardly from the surface of the substrate.

Cemented carbide substrates can also include one or more additives such as, for example, one or more of the following elements and/or their compounds: titanium, niobium, vanadium, tantalum, chromium, zirconium and/or hafnium. In some embodiments, titanium, niobium, vanadium, tantalum, chromium, zirconium and/or hafnium form solid solution carbides with WC of the substrate. In such embodiments, the substrate can include one or more solid solution carbides in an amount ranging from 0.1-5 weight percent. Additionally, a cemented carbide substrate can include nitrogen.

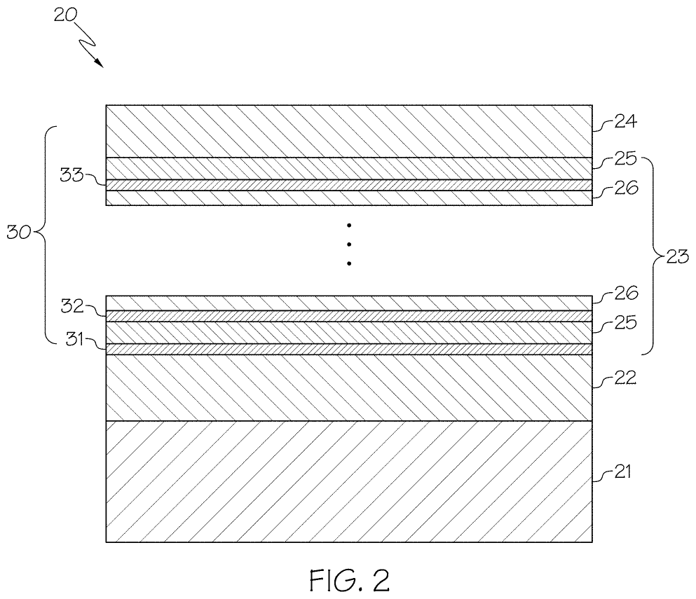

FIG. 2 is a representative view of a cross-section of a coating 20 of a coated body 10 according to an embodiment described herein. The coating 20 of the coated body 10 includes a main layer 22 adjacent to a substrate 21 and a multilayer 23 adjacent to the main layer 22. The coating may include one or more additional layers, such as an outermost indicator layer 24 overlying the multilayer 23.

The main layer 22 includes a nitride of at least Al and Ti. The main layer 22 may include a nitride of at least Al, Ti and at least one of Zr, Hf, and Cr. By way of example, the main layer 22 includes at least one of AlTiN and AlTiMeN, wherein Me is at least one of Zr, Hf, and Cr. In an aspect, the main layer 22 may have an average thickness of between 1 μm and 10 μm. In another aspect, the main layer 22 may have an average thickness of between 1 μm and 5 μm.

The multilayer 23 includes at least an oxide or oxynitride layer 25 and a nitride layer 26. Oxides or oxynitrides are hard and stable. However, oxides or oxynitrides are typically not used as single layers for wear protection due to inherent brittleness and reduced adhesion to the underlying substrate. Therefore, the oxide or oxynitride layer 25 may be combined with the main layer nitride 22 for better adhesion to the underlying substrate 21 and may be combined with the nitride layer 26 of the multilayer 23 for sufficient ductility of the coating 20.

In an aspect, the multilayer 23 may have an average total thickness of between 0.1 μm and 5 μm. The oxide or oxynitride layer 25 may have, for example, an average thickness of between 0.05 μm and 2.5 μm. The nitride layer 26 may have, for example, an average thickness of between 0.05 μm and 2.5 μm.

In another aspect, the multilayer 23 may include more than one of each of the oxide or oxynitride layer 25 and the nitride layer 26 alternating between the oxide or oxynitride layer 25 and the nitride layer 26. For example, the multilayer 23 may include between 1 to 10 iterations, preferably from 3 to 5 iterations, of each of the oxide or oxynitride layer 25 and the nitride layer 26 alternating between the oxide or oxynitride layer 25 and the nitride layer 26. The combined thickness of an oxide or oxynitride layer 25 and an adjacent nitride layer 26 is preferably in a range from about 0.1 μm to 1 μm. Each layer of the oxide or oxynitride layer 25 may have, for example, an average thickness of between 10 nm and 950 nm. Each layer of the nitride layer 26 may have, for example, an average thickness of between 10 nm and 950 nm.

In an aspect, the oxide or oxynitride layer 25 may be an oxide layer. In another aspect, the oxide or oxynitride layer 25 may be an oxynitride layer. The multilayer 23 may alternate between the oxynitride layer and the nitride layer 26. The oxynitride layer may have, for example, a nitrogen component of less than 50 atomic percent with respect to the proportion of nitrogen and oxygen in the oxynitride layer. The oxynitride layer particularly preferably contains 1 to 30 atomic percent nitrogen, preferably 2 to 15 atomic percent. The nitrogen content in the oxynitride layer may increase the bonding of the oxynitride layer to the multilayer nitride layer and/or the main layer nitride, and thus improving the wear resistance of the coating.

In an aspect, the oxide or oxynitride layer 25 of the multilayer 23 includes an oxide or oxynitride of at least one of Zr, Hf, and Cr. In another aspect, the oxide or oxynitride layer 25 of the multilayer 23 includes an oxide or oxynitride of Zr. By way of example, the oxide or oxynitride layer 25 of the multilayer 23 includes ZrO or ZrON.

In an aspect, the oxide or oxynitride layer 25 includes an oxide or oxynitride of Al and at least one of Zr, Hf, and Cr. In another aspect, the oxide or oxynitride layer 25 includes an oxide or oxynitride of Al and Zr. By way of example, the oxide or oxynitride layer 25 of the multilayer 23 includes AlZrO or AlZrON.

In an aspect, the nitride layer 26 of the multilayer 23 includes a nitride of at least one of Zr, Hf, and Cr. In another aspect, the nitride layer 26 of the multilayer 23 includes a nitride of Zr. By way of example, the nitride layer 26 of the multilayer 23 includes ZrN.

In an aspect, the nitride layer 26 of the multilayer 23 includes a nitride of Al and at least one of Zr, Hf, and Cr. In another aspect, the nitride layer 26 of the multilayer 23 includes a nitride of Al and Zr. By way of example, the nitride layer 26 of the multilayer 23 includes AlZrN.

Thus, the multilayer 23 may include alternating layers of an oxide or oxynitride layer 25 and a nitride layer 26, wherein the oxide or oxynitride layer 25 includes an oxide or oxynitride of at least one of Zr, Hf, and Cr, and wherein the nitride layer 26 includes a nitride of at least one of Zr, Hf, and Cr. The hardness of the Zr-, Hf-, or Cr-containing oxide or oxynitride layer 25 of the multilayer 23 of the present description is significantly increased compared to a typical titanium oxide or oxynitride layer. For example, zirconium oxide is harder than titanium oxide. Also, zirconium oxide has low thermal conductivity being constant over a broad range, and zirconium oxides have been successfully deposited by PVD with arc evaporation of zirconium in an oxygen containing atmosphere. However, while the Zr-, Hf-, or Cr-containing oxide and oxynitride layers 25 of the present description have higher hardness compared to a typical titanium oxide or oxynitride layer, they also have a challenge of how to improve transition and cohesion between the oxide and oxynitride layers 25 and adjacent nitride layers 22, 26 to avoid flaking due to differences in mechanical properties, lattice parameters, and surface energy.

To improve transition and cohesion between the oxide or oxynitride layers 25 and adjacent nitride layers 22, 26, the coating of the present description further include one or more metallic interlayers 30. By arranging the one or more metallic interlayers 30 between the oxide or oxynitride layer 25 and adjacent nitride layers 22, 26 lying below or above, an even better bond of the oxide or oxynitride layers 25 and adjacent nitride layers 22, 26 can be achieved. Thereby, the wear resistance of the coating 20 can thereby be further improved. Thus, the coating 20 of the present description includes a metallic interlayer 30 between the main layer 22 and the multilayer 23 or between the oxide or oxynitride layer 25 and the nitride layer 26 of the multilayer. In an aspect, a first metallic interlayer 31 is positioned between the main layer 22 and the multilayer 23. In another aspect, a second metallic interlayer 32 is positioned between the oxide or oxynitride layer 25 and the nitride layer 26 of the multilayer 23. In yet another aspect, a first metallic interlayer 31 is positioned between the main layer 22 and the multilayer 23, and a second metallic interlayer 32 is positioned between the oxide or oxynitride layer 25 and the nitride layer 26 of the multilayer 23. In the case of the coating 20 including more than one of each of the oxide or oxynitride layer 25 and the nitride layer 26 alternating between the oxide or oxynitride layer 25 and the nitride layer 26, the coating may include a second metallic interlayer 32 positioned between each oxide or oxynitride layer 25 and nitride layer 26 of the multilayer 23.

In an aspect, the metallic interlayers 30 may include, for example, at least one of Al, Zr, Hf, and Cr.

The metallic interlayers 30 may be defined by the presence of metallic bonding within the metallic interlayers 30. By including at least portions of the metallic interlayers 30 bonded by metallic bonding, the metallic interlayers 30 improve transition and cohesion between the oxide or oxynitride layer 25 on one side of the metallic interlayer 30 and the nitride layer 22, 26 on the other side of the metallic interlayer 30. The metallic interlayer 30 may further include the presence of, for example, oxides, nitrides, or oxynitrides.

The metallic interlayers 30 may have any thickness not inconsistent with the objectives of the present description. Decreasing a thickness of the metallic interlayers 30 too low may reduce cohesion between the oxide or oxynitride layer 25 and the adjacent nitride layer 22, 26. Accordingly, in an example, the metallic interlayers 30 may have an average thickness of at least 1 nm, preferably at least 5 nm. Increasing a thickness of the metallic interlayers 30 too high may diminish a hardness of the coating 20. Accordingly, in an example, the metallic interlayers 30 may have an average thickness of at most 50 nm, preferably at most 10 nm.

In an aspect, the coating 20 of the coated body 10 may further an outermost indicator layer 24 overlying the multilayer 23. The outermost indicator layer 24 preferably includes a non-grey colored material. The outermost indicator layer 24 makes it possible to discern with the naked eye the wear on of a cutting edge of a cutting tool which has been provided with this outermost layer. For example, the outermost indicator layer 24 preferably may include at least one of TiN, TiAlN, ZrN, ZrAlN, CrN, CrAIN, and HfN. In a specific example, the outermost indicator layer 24 includes Ti(1-x)AlxN, where x=0 to 40 mol. %.

In an aspect, a third metallic interlayer 33 may be positioned between the multilayer 23 and the outermost indicator layer 24 to improve transition and cohesion between the multilayer 23 and the outermost indicator layer 24.

According to the present description, a method for coating a substrate includes depositing a main layer on the substrate by physical vapor deposition under a nitrogen gas flow, in which the main layer includes a nitride of at least Al and Ti and depositing a multilayer on the main layer by physical vapor deposition by alternating between nitrogen gas flow and an oxygen or oxygen and nitrogen gas flow, in which the multilayer includes alternating layers of an oxide or oxynitride layer and a nitride layer, the oxide or oxynitride layer including an oxide or oxynitride of at least one of Zr, Hf, and Cr, and the nitride layer including a nitride of at least one of Zr, Hf, and Cr. According to the method the at least one of the gas flows during at least one of the steps of depositing the main layer and depositing the multilayer is reduced for a dwell period while continuing the physical vapor deposition to form a metallic interlayer between the main layer and the multilayer or between the oxide or oxynitride layer and the nitride layer of the multilayer. By way of reducing a gas flow during at least one of the steps of depositing the main layer and depositing the multilayer, promotion of the formation of the metallic interlayer is facilitated.

In an aspect, the step of reducing the gas flows may include stopping the gas flow. Thus, the at least one of the gas flows during at least one of the steps of depositing the main layer and depositing the multilayer may be stopped for a dwell period while continuing the physical vapor deposition to form a metallic interlayer between the main layer and the multilayer or between the oxide or oxynitride layer and the nitride layer of the multilayer. By way of stopping a gas flow during at least one of the steps of depositing the main layer and depositing the multilayer, promotion of the formation of the metallic interlayer is further facilitated and the metallic characteristics of the metallic interlayer is increased.

In an aspect, the dwell period for reducing or stopping the gas flow may be in a range of 10-30 seconds.

In an aspect, the method for coating a substrate may further include depositing an outermost indicator layer on the multilayer by physical vapor deposition under a nitrogen gas flow. To form a metallic interlayer between the multilayer and the outermost indicator layer, the gas flow at the end of the step of depositing the multilayer may be reduced or stopped for a dwell period while continuing the physical vapor deposition.

In an aspect, one or more the above-described layers of the coating are applied by physical vapor deposition (PVD), such as by cathode sputtering or arc evaporation. During sputtering, atoms are ejected from a cathode metal (target) due to bombardment of the target by energetic ions from a plasma and then the ejected atoms are deposited onto a substrate arranged in the vicinity of the target. In the presence of a reactive gas, conversion products from the target atoms and the reactive gas then form on the substrate. An inert gas such as argon is usually used as the sputtering gas to generate the plasma. During arc evaporation, a cathode metal target is vaporized by an electric arc and then the vaporized metal is deposited onto a substrate arranged in the vicinity of the target. Physical vapor deposition of a layer results in a coating layer that is physically bonded to the substrate or underlying layer.

The main layer and the multilayer, including the alternating layers of an oxide or oxynitride layer and nitride layer and the metallic interlayers, may be substantially deposited by any PVD method which is suitable therefor. However, magnetron sputtering, reactive magnetron sputtering, dual magnetron sputtering, high-power-impulse magnetron sputtering (HIPIMS) or the simultaneous use of cathode sputtering (sputter deposition) and arc vaporization (arc PVD) are preferred. Particularly, all layers of the coating may be deposited by arc vapor deposition (arc PVD) since particularly hard and dense layers can be deposited by this method. Pulsing of source power can add to performance of coatings due to lower stress and higher density.

### Comparative Example 1

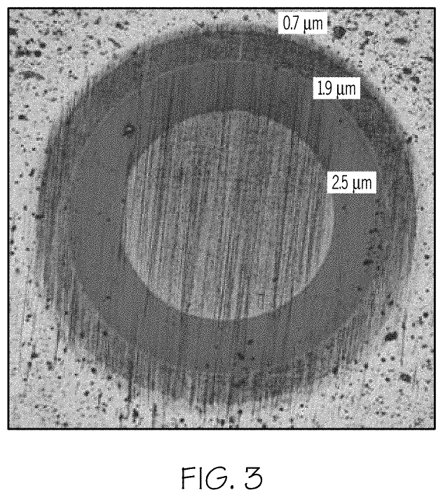

As shown in FIG. 3, a coating was applied to a substrate by physical vapor deposition. The coating includes an AlTiN main layer having an average thickness of about 2.5 μm, a zirconium oxide layer having an average thickness of about 1.9 μm on the main layer, and a zirconium nitride layer having an average thickness of less than 0.7 μm on the zirconium oxide layer. The resulting coating showed flaking and poor cohesion between the AlTiN main layer and the zirconium oxide layer.

### Inventive Example 1

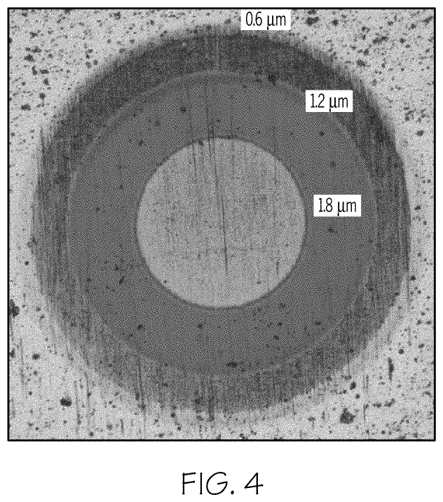

As shown in FIG. 4, a coating was applied to a substrate by physical vapor deposition. The coating includes an AlTiN main layer having an average thickness of about 1.8 μm, a zirconium oxide layer having an average thickness of about 1.2 μm on the main layer, and a zirconium nitride layer having an average thickness of less than 0.6 μm on the zirconium oxide layer. To form a metallic interlayer between the main layer and zirconium oxide layer, the gas flow of nitrogen after depositing the main layer was stopped while continuing the physical vapor deposition forming a metallic interlayer of about 10 nm between the main layer and zirconium oxide layer. The resulting coating showed no flaking and good cohesion between the AlTiN main layer and the zirconium oxide layer.

Although various embodiments of the disclosed coated body and method for coating have been shown and described, modifications may occur to those skilled in the art upon reading the specification. The present application includes such modifications and is limited only by the scope of the claims.

1. A coated body having a substrate and a coating applied to the substrate by physical vapor deposition, the coating comprising:
a main layer adjacent to the substrate, wherein the main layer comprises a nitride of at least Al and Ti;
a multilayer adjacent to the main layer, wherein the multilayer comprises alternating layers of an oxide or oxynitride layer and a nitride layer, wherein the oxide or oxynitride layer comprises an oxide or oxynitride of at least one of Zr, Hf, and Cr, and wherein the nitride layer comprises a nitride of at least one of Zr, Hf, and Cr; and
a metallic interlayer between the oxide or oxynitride layer and the nitride layer of the multilayer.

2. The coated body of claim 1, wherein the main layer comprises at least one of AlTiN and AlTiMeN, wherein Me is at least one of Zr, Hf, and Cr.

3. The coated body of claim 1, wherein the oxide or oxynitride layer comprises an oxide or oxynitride of Zr.

4. The coated body of claim 1, wherein the oxide or oxynitride layer comprises an oxide or oxynitride of Al and at least one of Zr, Hf, and Cr.

5. The coated body of claim 1, wherein the oxide or oxynitride layer comprises an oxide or oxynitride of Al and Zr.

6. The coated body of claim 1, wherein the nitride layer comprises a nitride of Zr.

7. The coated body of claim 1, wherein the nitride layer comprises a nitride of Al and at least one of Zr, Hf, and Cr.

8. The coated body of claim 1, wherein the nitride layer comprises a nitride of Al and Zr.

9. The coated body of claim 1, wherein the main layer has an average thickness of between 1 μm and 10 μm.

10. The coated body of claim 1, wherein the oxide or oxynitride layer has an average thickness of between 10 nm and 200 nm.

11. The coated body of claim 1, wherein the nitride layer has an average thickness of between 10 nm and 200 nm.

12. The coated body of claim 1, wherein multilayer has an average thickness of between 0.1 μm and 5 μm.

13. A coated body having a substrate and a coating applied to the substrate by physical vapor deposition, the coating comprising:
a main layer adjacent to the substrate, wherein the main layer comprises a nitride of at least Al and Ti;
a multilayer adjacent to the main layer, wherein the multilayer comprises alternating layers of an oxide or oxynitride layer and a nitride layer, wherein the oxide or oxynitride layer comprises an oxide or oxynitride of at least one of Zr, Hf, and Cr, and wherein the nitride layer comprises a nitride of at least one of Zr, Hf, and Cr, wherein multilayer has between 1 to 5 of each of the alternating layers of the oxide or oxynitride layer and the nitride layer; and
a metallic interlayer between the main layer and the multilayer or between the oxide or oxynitride layer and the nitride layer of the multilayer.

14. The coated body of claim 1, wherein the metallic interlayer comprises at least one of Al, Zr, Hf, and Cr.

15. The coated body of claim 1, wherein the metallic interlayer has an average thickness of between 1 nm and 50 nm.

16-17. (canceled)

18. The coated body of claim 1, further comprising an outermost indicator layer overlying the multilayer.

19. (canceled)

20. The coated body of claim 18, wherein further comprising a metallic interlayer between the multilayer and the outermost indicator layer.

21. A method for coating a substrate, the method comprising:
depositing a main layer on the substrate by physical vapor deposition under a nitrogen gas flow, the main layer comprising a nitride of at least Al and Ti; and
depositing a multilayer on the main layer by physical vapor deposition by alternating between nitrogen gas flow and an oxygen or oxygen and nitrogen gas flow, the multilayer comprising alternating layers of an oxide or oxynitride layer and a nitride layer, wherein the oxide or oxynitride layer comprises an oxide or oxynitride of at least one of Zr, Hf, and Cr, and wherein the nitride layer comprises a nitride of at least one of Zr, Hf, and Cr,
wherein the at least one of the gas flows during at least one of the steps of depositing the main layer and depositing the multilayer is reduced for a dwell period while continuing the physical vapor deposition to form a metallic interlayer between the main layer and the multilayer or between the oxide or oxynitride layer and the nitride layer of the multilayer.

22-27. (canceled)
